(19) United States
(12) Patent Application Publication
(10) Pub. No.: US 2018/0136702 A1
(43) Pub. Date: May 17, 2018

(54) COOLING FAN AND ELECTRONIC DEVICE HAVING THE SAME

(71) Applicant: Foxconn Technology Co., Ltd., New Taipei (TW)

(72) Inventors: MING-HSIU CHUNG, New Taipei (TW); YU-KAI TAI, New Taipei (TW)

(21) Appl. No.: 15/469,645

(22) Filed: Mar. 27, 2017

(30) Foreign Application Priority Data
Nov. 14, 2016 (TW) 105137045

(51) Int. Cl. G06F 1/20; H05K 7/20; G06F 1/16

(52) U.S. Cl. CPC G06F 1/20; H05K 7/20; H05K 7/20745; H05K 7/20727; G06F 1/16

(57) ABSTRACT

A cooling fan includes a base plate and a central tube connected to a center of the base plate. The central tube is made of metal by injection molding, and is a hollow cylinder with both ends open. An outer circumferential surface of one end adjacent to the base plate is connected to the base plate by laser welding, thereby forming a melted layer at a connecting portion between the outer circumferential surface of the end and the base plate.

The subject matter relates to a cooling fan and an electronic device having the cooling fan.

### BACKGROUND

Heat generating components such as central processing units (CPUs) generate heat when in operation. In an electronic device that employs the CPU, a cooling fan can be used for dissipate the heat.

A typical cooling fan includes a stator, a rotor able to rotate with respect to the stator, and a base supporting the stator and the rotor. A central tube is usually mounted to a center portion of the base. When the central tube is made of plastic, the size of the central tube may be more imprecise when manufactured, which may result in a leakage of oil and a poor heat dissipation efficiency. When the central tube is made of metal, the heat dissipation efficiency can be improved. However, riveting the central tube to the base improves the connecting strength but increases the manufacturing cost.

Therefore, there is room for improvement within the art.

### BRIEF DESCRIPTION OF THE DRAWINGS

Implementations of the present technology will now be described, by way of example only, with reference to the attached figures.

FIG. 1 is a diagrammatic view of an exemplary embodiment of an electronic device.

FIG. 2 is a diagrammatic view of a cross-section of a cooling fan in the electronic device of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

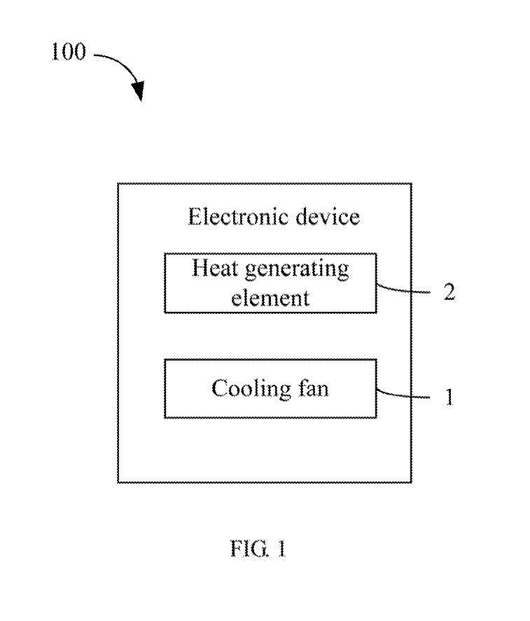

FIG. 1 illustrates an exemplary embodiment of an electronic device 100. The electronic device 100 comprises at least one heat generating element 2 and a cooling fan 1 for dissipating the heat generated by the heat generating element 2. In at least one exemplary embodiment, the electronic device 100 can be a computer. The heat generating element 2 can be a CPU.

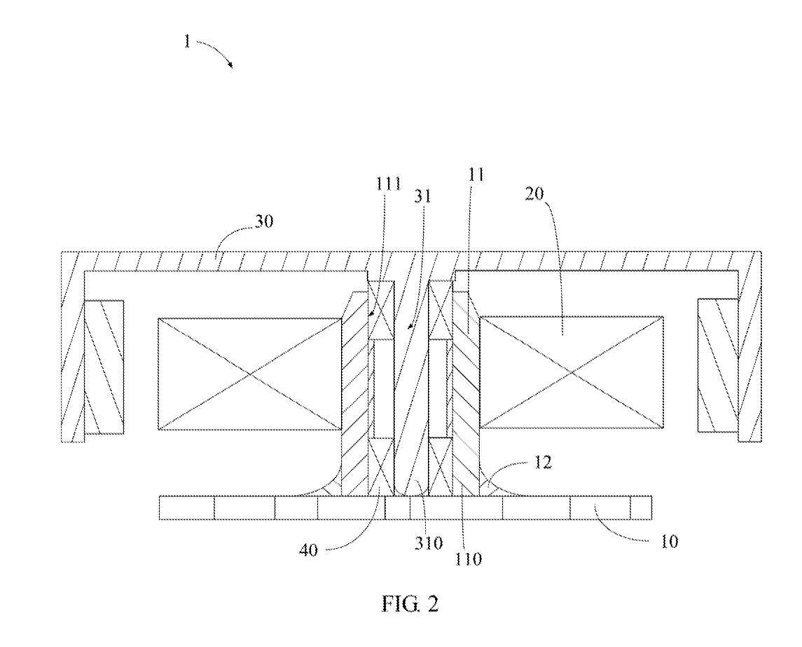

FIG. 2 illustrates that the cooling fan 1 comprises a stator 20, a rotor 30 capable of rotating relative to the stator 20, and a base plate 10 for supporting the stator 20 and the rotor 30.

The base plate 10 is substantially flat. A central tube 11, which is made of metal (such as aluminum) by injection molding, is connected to the center of the base plate 10. The central tube 11 is a hollow cylinder with two open ends 110. An outer circumferential surface of one end 110 adjacent to the base plate 10 is connected to the base plate 10 by laser welding, thereby forming a melted layer 12 at a connecting portion between the outer circumferential surface of the end 110 and the base plate 10.

The central tube 11 further comprises a receiving hole 111 for receiving a bearing 40.

The stator 20 is wrapped around the central tube 11. The stator 20 comprises a shaft 31. A free end 310 of the shaft 31 passes through the bearing hole of the bearing 40 to abut the base plate 10.

Since the central tube 11 is connected to the base plate 10 by laser welding, the connecting strength between the central tube 11 and the base plate 10 is improved. Furthermore, the laser welding process is simple which decreases the manufacturing cost. Moreover, since the central tube 11 is a simple hollow cylinder, no riveting hole for connecting purpose is required. The structure of the central tube 11 being simplified further decreases the manufacturing cost.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments, to the full extent indicated by the plain meaning of the terms in which the appended claims are expressed.

What is claimed is:

1. A cooling fan comprising:
a base plate; and
a central tube connected to a center of the base plate, the central tube made of metal by injection molding and being a hollow cylinder with two open ends, an outer circumferential surface of one of the two open ends adjacent to the base plate connected to the base plate by laser welding, thereby forming a melted layer at a connecting portion between the outer circumferential surface and the base plate.

2. The cooling fan of claim 1, further comprising a stator and a rotor capable of rotating relative to the stator, wherein the base plate supports the stator and the rotor.

3. The cooling fan of claim 2, wherein the central tube further comprises a receiving hole for receiving a bearing; the stator comprises a shaft; a free end of the shaft passes through the bearing to abut the base plate.

4. The cooling fan of claim 3, wherein the stator is wrapped around the central tube.

5. The cooling fan of claim 1, wherein the central tube is made of metal.

6. The cooling fan of claim 5, wherein the central tube is made of aluminum.

7. The cooling fan of claim 1, wherein the base plate is substantially flat.

8. An electronic device comprising:
at least one heat generating element; and
a cooling fan for dissipating heat generated by the at least one heat generating element, the cooling fan comprising:
a base plate; and
a central tube connected to a center of the base plate, the central tube made of metal by injection molding and being a hollow cylinder with two open ends, an outer circumferential surface of one of the two open ends adjacent to the base plate connected to the base plate by laser welding, thereby forming a melted layer at a connecting portion between the outer circumferential surface and the base plate.

9. The electronic device of claim 8, wherein the cooling fan further comprises a stator and a rotor capable of rotating relative to the stator; the base plate supports the stator and the rotor.

10. The electronic device of claim 9, wherein the central tube further comprises a receiving hole for receiving a bearing; the stator comprises a shaft; a free end of the shaft passes through the bearing to abut the base plate.

11. The electronic device of claim 10, wherein the stator is wrapped around the central tube.

12. The electronic device of claim 8, wherein the central tube is made of metal.

13. The electronic device of claim 12, wherein the central tube is made of aluminum.

14. The electronic device of claim 8, wherein the base plate is substantially flat.

15. The electronic device of claim 8, the heat generating element is a central processing unit.

16. A cooling fan comprising:
a base plate; and
a central tube connected to the base plate, the central tube made of metal by injection molding and having two open ends, an outer circumferential surface of one of the two open ends adjacent to the base plate connected to the base plate by laser welding, thereby forming a melted layer at a connecting portion between the outer circumferential surface and the base plate.

17. The cooling fan of claim 16, further comprising a stator and a rotor capable of rotating relative to the stator, wherein the base plate supports the stator and the rotor.

18. The cooling fan of claim 17, wherein the central tube further comprises a receiving hole for receiving a bearing; the stator comprises a shaft; a free end of the shaft passes through the bearing to abut the base plate.

19. The cooling fan of claim 18, wherein the stator is wrapped around the central tube.

20. The cooling fan of claim 16, wherein the central tube is made of aluminum.
